(19) United States
(12) Patent Application Publication
(10) Pub. No.: US 2022/0357609 A1
(43) Pub. Date: Nov. 10, 2022

(54) TOUCH ELEMENT AND DISPLAY DEVICE INCLUDING THE SAME

(71) Applicant: TPK Touch Solutions (Xiamen) Inc., Xiarnen (CN)

(72) Inventors: Ming-Chung Liu, Miaoli County (TW); Yi-Lung Yang, Taoyuan City (TW); Sheng-Fa Liu, Taoyuan City (TW); Chun-Chi Lin, Yunlin County (TW); Wei-Chou Chen, Taoyuan City (TW); Chun-Hung Chu, Hsinchu City (TW)

(21) Appl. No.: 17/313,228

(22) Filed: May 6, 2021

(51) Int. Cl. G02F 1/1333; G02F 1/13363; G02F 1/1335

(52) U.S. Cl. CPC G02F 1/13338; G02F 1/13363; G02F 1/133541

(57) ABSTRACT

A touch element includes a polymer phase retardation layer and a touch sensing structure. The polymer phase retardation layer receives the linearly polarized incident light and then produces a phase difference. The touch sensing structure is disposed on the polymer phase retardation layer.

### BACKGROUND

### 1. Field of the Disclosure

The present disclosure relates to a touch element, and more particularly, to an ultra-thin touch element that is bendable and resistant to high temperatures.

### 2. Related Art

At present, a circular polarizer (CPOL) mainly has a phase retarder (also referred to herein as a phase retardation layer) and a linear polarizer (also referred to herein as a linear polarization layer), which is often used as an anti-reflection film in the display field to solve the display problem caused by the reflected light generated by the incident light from the external environment. The phase retardation layer used can be a quarter wave plate (QWP). FIG. 1 is a schematic diagram illustrating that a circular polarizer or an anti-reflection sheet 100a receives incident light L from the external environment. As shown in FIG. 1, when the incident light L from the external environment passes through an outermost linear polarization layer 10a, the incident light L is converted into linear polarization incident light L₁ by the linear polarization layer 10a. The polarization direction of the linear polarization incident light L₁ is the vertical direction. Then, the linear polarization incident light L₁ enters a quarter-wave plate, which is used as a phase retardation layer 20a, so that the linear polarization incident light L₁ produces a phase retardation, and the linear polarization incident light L₁ is converted into a left-handed polarized light L_{cl}. After being reflected by a display panel 200, the left-handed polarized light L_{cl} will be formed to be a reverse right-handed polarized light L_{cr}, then the right-handed polarized light L_{cr} passes through the quarter-wave plate used as the phase retardation layer 20a to form linear polarization incident light L₂. The polarization direction of the linear polarization incident light L₂ is orthogonal to the polarization direction of the linear polarization incident light L₁, so that the incident light L from the external environment cannot pass through the linear polarization layer 10a and thus is blocked in the anti-reflection sheet 100a.

In addition, the anti-reflection sheet 100a may be assembled with a touch sensing structure 30a to form an integrated product. FIG. 2 is a schematic diagram of a structure of the integrated anti-reflection sheet 100a and the touch sensing structure 30a in the related art. As shown in FIG. 2, the material of the phase retardation layer 20a is usually anisotropic liquid crystal (and the phase retardation layer 20a is also called a liquid crystal phase retardation layer). The problem thereof is that the substrate 20c must be used as the basic material during the manufacturing process of the anisotropic liquid crystal to provide mechanical strength, which will result in a thicker anti-reflection sheet, and the conventional circular polarizer must be provided with another transparent adhesive layer 20b, which is assembled with the touch sensing structure 30a, resulting in the thickness of the final anti-reflection sheet reaching 64 μm. This does not conform to the current trend of increasingly thinner and lighter displays, so it is necessary to make the anti-reflection sheet thinner.

In addition, as disclosed in KR 102146739 (KR '739), various types of touch sensors, such as glass-film sensor-film sensor (GFF), glass-film having double-side sensor (GF2), etc. can be attached to the phase retardation layer. However, the phase retardation layer is an optical element, but the touch sensor is an electrical component in the present disclosure. When two components with different functions are directly coupled together, it must be considered whether the respective characteristics will be affected by another component and become invalid. That is, KR '739 just broadly discloses a possibility of the phase retardation layer in combination with the touch sensor module, but KR '739 has not proved that the touch sensor module will not cause the shift of the characteristics of the phase retardation layer (such as the phase retardation value).

Furthermore, with respect to the material of the phase retardation layer 20a, KR '739 discloses that the material of the phase retardation layer 20a can be an anisotropic liquid crystal or a thin-film phase retardation layer made of polymer. However, it is doubtful whether the product with the anisotropic liquid crystal used as the phase retardation layer 20a is reliable. Refer to FIG. 3 first, which is the result of a weather resistance simulation experiment under a high temperature environment. FIG. 3 shows that the difference of the phase retardation value of the liquid crystal phase retardation layer is greater than 7 nm in the visible light range in the high temperature test. For example, under the condition of a wavelength of 575 nm, the difference of the retardation value (the absolute value of the difference) is 7.2. This experimental result represents the optical function (such as the aforementioned anti-reflection function) of the product, in which a liquid crystal retardation layer is used in an anti-reflection sheet, will be degraded due to environmental conditions, use status, etc., and the display effect of the terminal product will thus be affected. That is, KR '739 just broadly discloses a possibility of the phase retardation layer in combination with the touch sensor module, but did not recognize the problem that the reliability of the liquid crystal phase retardation layer could not meet the requirement.

Therefore, the present disclosure is provided for the above-mentioned deficiencies.

### SUMMARY OF THE DISCLOSURE

An objective of the present disclosure is to provide a touch element, wherein the touch element is formed by integrating an electrical signal processing element (touch sensing structure) and an optical element (polymer phase retardation layer). The structure of the touch sensor includes silver nanowires. The two components with different characteristics/functions are coupled together, and the respective characteristics will not be affected by another component, which is in conformity with the integration requirement.

An objective of the present disclosure is to provide a touch element. The touch element can maintain a very low difference of the phase retardation value after being kept at a high temperature for a period of time. The difference of the phase retardation value of the polymer phase retardation layer of the touch element within the visible light range can be less than 7.0 nm or less than 2.0 nm, or can be between 0 nm to 2.0 nm, 0.1 nm to 2.0 nm, 0.2 nm to 2.0 nm, 0.3 nm to 2.0 nm, 0.2 nm to 1.0 nm, 0.3 nm to 0.7 nm, or 0.7 nm to 2.0 nm; therefore the touch elements and products with high reliability can be realized.

Another objective of the present disclosure is to provide a touch element. The polymer phase retardation layer of the touch element can be directly used as a substrate, and thus an additional substrate is not needed. The thickness of the polymer phase retardation layer according to the present disclosure is less than 53 μm, so that a bendable and ultra-thin touch element and the product thereof can be realized.

In order to achieve the above objective, the present disclosure provides a touch element, including: a polymer phase retardation layer and a touch sensing structure configured to contact with the polymer phase retardation layer, wherein the touch sensing structure is a composite layer of silver nanowires and a polymer. In a visible light range, a difference of phase retardation values R₀ of the touch element and a phase retardation value R₀ of the polymer phase retardation layer between before the touch sensing structure is disposed is less than 1%.

Preferably, according to the touch element of the present disclosure, a thickness of the touch element is less than 64 μm.

Preferably, according to the touch element of the present disclosure, a thickness of the polymer phase retardation layer is less than 53 μm.

Preferably, according to the touch element of the present disclosure, a phase retardation difference ΔR₀ of the touch element is expressed by the following formula:

ΔR₀=R₀−R₀′

wherein R₀ represents a first phase retardation value of the touch element measured at a wavelength of 575 nm while the touch element has a temperature of about 25° C., R₀′ represents a second phase retardation value of the touch element measured at the wavelength of 575 nm after the touch element lasted for 240 hours at 85° C. and returned to about 25° C., ΔR₀ represents an absolute value of a difference between the first phase retardation value and the second phase retardation value, and the ΔR₀ is less than 7.0 nm.

Preferably, according to the touch element of the present disclosure, the ΔR₀ is between 0 nm to 2.0 nm, 0.1 nm to 2.0 nm, 0.2 nm to 2.0 nm, 0.3 nm to 2.0 nm, 0.2 nm to 1.0 nm, 0.3 nm to 0.7 nm, or 0.7 nm to 2.0 nm.

Preferably, according to the touch element of the present disclosure, a thickness of the polymer phase retardation layer is about 13 μm, and a phase retardation difference ΔR₀ of the touch element is expressed by the following formula:

ΔR₀=R₀−R₀′

wherein R₀ represents a first phase retardation value of the touch element measured at a wavelength of 575 nm while the touch element has a temperature of about 25° C., R₀′ represents a second phase retardation value of the touch element measured at the wavelength of 575 nm after the touch element lasted for 240 hours at 85° C. and returned to about 25° C., ΔR₀ represents an absolute value of a difference between the first phase retardation value and the second phase retardation value, and the ΔR₀ is between 0 nm to 1.0 nm, 0.1 nm to 1.0 nm, 0.2 nm to 1.0 nm, or is 0.7 nm.

Preferably, according to the touch element of the present disclosure, a thickness of the polymer phase retardation layer is about 25 μm, and a phase retardation difference ΔR₀ of the touch element is expressed by the following formula:

ΔR₀=R₀−R₀′

wherein R₀ represents a first phase retardation value of the touch element measured at a wavelength of 575 nm while the touch element has a temperature of about 25° C., R₀′ represents a second phase retardation value of the touch element measured at the wavelength of 575 nm after the touch element lasted for 240 hours at 85° C. and returned to about 25° C., ΔR₀ represents an absolute value of a difference between the first phase retardation value and the second phase retardation value, and the ΔR₀ is between 0 nm to 2.0 nm, 0.1 nm to 2.0 nm, 0.2 nm to 2.0 nm, 0.3 nm to 2.0 nm, or is 0.3 nm.

Preferably, according to the touch element of the present disclosure, the touch element is assembled in a linear polarization layer.

Further, in order to achieve the above-mentioned objective, the present disclosure based on the above-mentioned touch element further provides a display device including: a display panel having a display area and the above-mentioned touch element disposed on the display panel, wherein the touch sensing structure of the touch element correspondingly overlaps the display area.

Preferably, according to the display device of the present disclosure, the display panel is, but is not limited to, a liquid crystal display panel, an organic electroluminescence display panel, an organic light emitting diode display panel, or a micro light emitting diode display panel.

In order to enable those skilled in the art to understand the purpose, features and effects of the present disclosure, the following specific embodiments and accompanying drawings are used to explain the present disclosure in detail as follows.

### BRIEF DESCRIPTION OF THE DRAWINGS

FIG. 1 is a schematic diagram of a circular polarizer receiving an incident light from an external environment, illustrating the principle of anti-reflection;

FIG. 2 is a schematic diagram illustrating an integrated structure of an anti-reflection sheet and a touch sensing structure of the related art;

FIG. 3 is a curve diagram of the difference of the phase retardation value of the liquid crystal phase retardation layer of the related art after the reliability test versus the wavelength;

FIG. 4 is a schematic diagram illustrating the structure of the touch element according to a first embodiment of the present disclosure;

FIG. 5 is a curve diagram of the difference of the phase retardation value of the touch element according to a first embodiment of the present disclosure and the related art;

FIG. 6 is a schematic diagram illustrating the structure of the touch element according to another embodiment of the present disclosure;

FIG. 7 is a schematic diagram illustrating the structure of the touch element according to another embodiment of the present disclosure; and

FIG. 8 is a schematic diagram illustrating the structure of the display device according to an embodiment of the present disclosure.

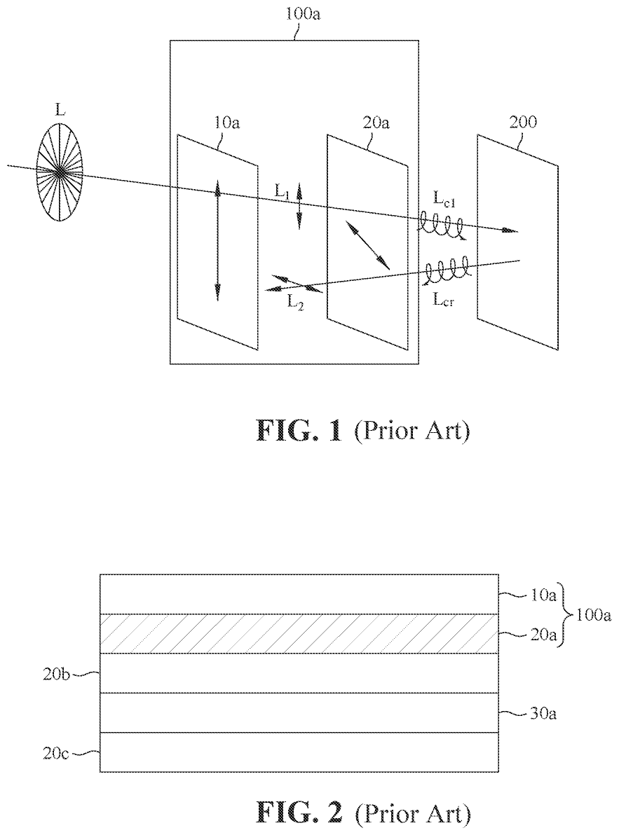

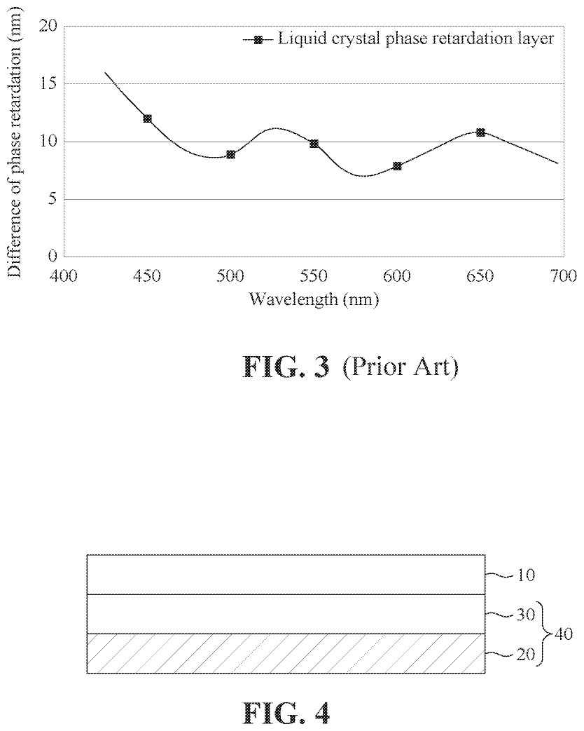

### DETAILED DESCRIPTION

Hereinafter, the exemplary embodiments according to the present disclosure will be described in more detail with reference to the accompanying drawings, and the advantages, features, and methods of achieving the present disclosure will be clear. However, it should be noted that the present disclosure is not limited to the following exemplary embodiments, but can be implemented in various forms.

The terms used herein are only used to illustrate specific embodiments and are not intended to limit the present disclosure. Unless further clearly indicated in the context, otherwise, the terms “a” and “the” in the singular form used herein also include the plural form. Unless further clearly indicated in the context, otherwise, the terms “weatherability” and “reliability” used herein should be understood as the same concept.

In addition, it should be understood that when an element is referred to as being “on” another element, the element may be directly on the other element, or an intervening elements may be present. In addition, the referred thickness values herein are not absolute. Those skilled in the art can understand that the referred thickness may include manufacturing tolerances, measurement errors, etc. Preferably, the thicknesses listed herein may be in a range of 10% or 20%.

It should also be understood that although the terms “first”, “second”, etc. may be used in this specification to describe various elements, these elements should not be limited to these terms. These terms are only used to distinguish each element. Therefore, the first element in other embodiments may be referred to as the second element without departing from the teachings of the present disclosure. In this specification, the same reference numerals denote the same elements.

Please refer to FIG. 4, which is a schematic diagram of a touch element 40 of the present disclosure. The touch element 40 according to the present disclosure includes: a polymer phase retardation layer 20 and a touch sensing structure 30 configured to contact the polymer phase retardation layer 20. A combination of the touch element 40 and a linear polarization layer 10 can constitute an anti-reflection optical element of the embodiment of the present disclosure, such as a circular polarizer. That is, the anti-reflection optical element of the embodiment of the present disclosure is a multifunctional module having touch sensing function and optical function at the same time, and the touch sensing structure 30 does not affect the optical characteristics of the polymer phase retardation layer 20.

Specifically, with reference to FIG. 4 and with reference to the foregoing description of FIG. 2, the linear polarization layer 10 receives an incident light L from an external environment and converts the incident light L into a linear polarization incident light L₁. In a preferred embodiment of the present disclosure, the linear polarization incident light L₁ has a vertical polarization direction. However, the present disclosure is not limited to this.

The polymer phase retardation layer 20 in FIG. 4 can also be called a thin-film phase retardation layer or a stretched phase retardation layer, which is arranged below the linear polarization layer 10. The polymer phase retardation layer 20 receives the linear polarization incident light L₁ so that the linear polarization incident light L₁ produces a phase retardation. In a preferred embodiment of the present disclosure, the phase retardation causes the linear polarization incident light L₁ to be converted into a left-handed polarized light L_{cl}, and the left-handed polarized light L_{cl} has a polarization direction of the left-handed circle polarization. Then, when the left-handed polarized light L_{cl} is reflected by the display panel 200, the left-handed polarized light L_{cl} will form a reverse right-handed polarized light L_{cr}, and the right-handed polarized light L_{cr} then passes through the polymer phase retardation layer 20 to form linear polarization incident light L₂. The polarization direction of the linear polarization incident light L₂ is orthogonal to the linear polarization direction of the linear polarization incident light L₁, so that the incident light from the external environment cannot pass through the linear polarization layer 10 and is blocked in the touch element 40. However, the present disclosure is not limited to this.

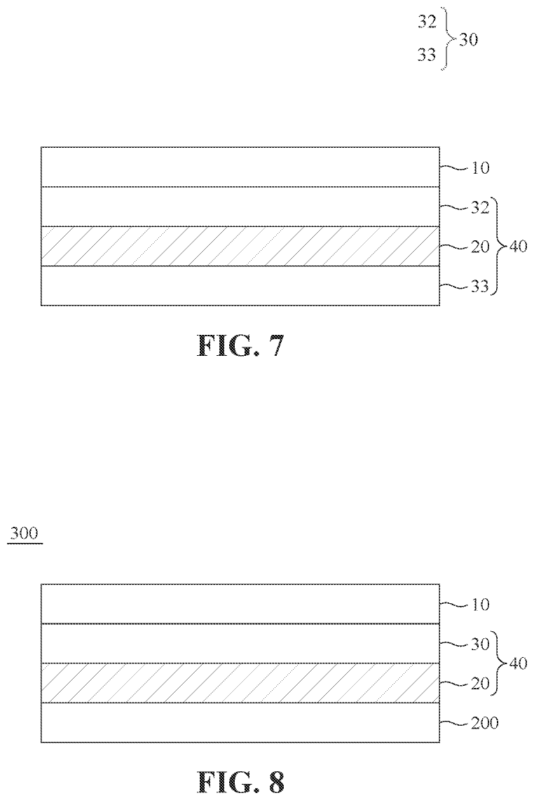

Specifically, with reference to FIG. 4, the touch sensing structure 30 is disposed on and in contact with the polymer phase retardation layer 20. For example, the touch sensing structure 30 may form a single-layer electrode structure. In some embodiments, the touch sensing structure 30 includes a single-layer touch electrode layer, and the single-layer touch electrode layer may be provided above the polymer phase retardation layer 20, that is, the single-layer touch electrode layer is between the polymer phase retardation layer 20 and the linear polarization layer 10. In addition, in some embodiments, the single-layer touch electrode layer may be disposed under the polymer phase retardation layer 20. With reference to FIG. 7, the polymer phase retardation layer 20 is formed between the touch sensing structure 30 and the linear polarization layer 10. In addition, the touch sensing structure 30 may form a double-layer electrode structure. In some embodiments, the touch sensing structure 30 includes a first touch electrode layer 32 and a second touch electrode layer 33. The first touch electrode layer 32 is disposed between the linear polarization layer 10 and the polymer phase retardation layer 20, and the second touch electrode layer 33 is disposed under the polymer phase retardation layer 20.

Please refer to FIG. 4, which is a schematic diagram illustrating the structure of the touch element according to the first embodiment of the present disclosure. As shown in FIG. 4, the touch element 40 according to the present disclosure includes: the polymer phase retardation layer 20 and the touch sensing structure 30 configured to contact the polymer phase retardation layer 20. Similarly, the linear polarization layer 10 of the present embodiment is disposed on the touch sensing structure 30 to form the anti-reflection optical element of the embodiment of the present disclosure.

Specifically, with reference to FIG. 4, the polymer phase retardation layer 20 is disposed under the linear polarization layer 10. The polymer phase retardation layer 20 receives the linear polarization incident light L₁ and causes the linear polarization incident light L₁ to produce a phase retardation. In this embodiment, the material of the polymer phase retardation layer 20 is colorless polyimide (CPI), wherein the polyimide has excellent mechanical characteristics, heat resistance, chemical resistance, and electrical insulation property. However, the present disclosure is not limited to this. It should be further explained that the colorless polyimide according to the present disclosure is produced by the condensation reaction of diamine monomer and dianhydride monomer, wherein the ratio of diamine monomer to dianhydride monomer ranges from 0.95-0.05:0.05-0.95. However, the present disclosure is not limited to this.

It is worth mentioning that, in the embodiment of the present disclosure, the touch sensing structure 30 includes metal nanowires (such as silver nanowires), and the method used can be coating a dispersion liquid including silver nanowires on the polymer phase retardation layer 20, for example, mixing silver nanowires into a solvent, such as water, alcohol, ketone, ether, hydrocarbon, or aromatic solvent (benzene, toluene, xylene, etc.) to form a coating/slurry. The above-mentioned coating/slurry may also include additives, surfactants or adhesives, such as carboxymethyl cellulose (CMC), hydroxyethyl cellulose (HEC), hydroxypropyl methylcellulose (HPMC), sulfonate, sulfate, disulfonate, sulfosuccinate, phosphate, fluorine-containing surfactant, etc. After the coating is completed, the silver nanowire layer is formed through a curing step. The silver nanowire layer can be formed by a patterning method known to those skilled in the art to form the touch sensing structure 30, so that the touch sensing structure 30 is arranged on the polymer phase retardation layer 20 and is in contact with the polymer phase retardation layer 20.

Preferably, the silver nanowires are fixed on the surface of the polymer phase retardation layer 20 without falling off to form the silver nanowire layer, and the silver nanowires can be in contact with each other to provide a continuous current path to further form a conductive network. In other words, the silver nanowires are in contact with each other at the intersections thereof to form a path for transferring electrons. That is, one silver nanowire layer and another silver nanowire layer will be in direct contact at the intersection, thus forming a low-resistance electron transfer path. In an embodiment, when the sheet resistance of a region or a structure is higher than 10⁸ ohm/square, preferably higher than 10⁴ ohm/square, 3000 ohm/square, 1000 ohm/square, 350 ohm/square, or 100 ohm/square, the region or the structure can be regarded as electrical insulation. In an embodiment, the sheet resistance of the silver nanowire layer including the silver nanowires is less than 100 ohm/square.

In one embodiment, a polymer layer may be further provided so that the polymer layer covers the silver nanowire. In a specific embodiment, a suitable polymer/polymeric substance is coated on the silver nanowires, and the polymer with fluid state/property can penetrate between the silver nanowires to form a filler, and the silver nanowires will be embedded in the polymer/polymeric substance. A composite structure will be formed after the polymer is cured. That is, in this step, the polymer/polymeric substance is coated with a polymer layer on the silver nanowire, and the silver nanowire is embedded in the polymer layer to form the composite structure. In some embodiments of the present disclosure, the polymer layer is formed of an insulation material. For example, the material of the polymer layer can be non-conductive resin or other organic materials, such as polyacrylate, epoxy resin, polyurethane, polysiloxane, poly(silicon-acrylic), polyethylene (PE), polypropylene (PP), polyvinyl butyral (PVB), polycarbonate (PC), acrylonitrile butadiene styrene (ABS), poly-3,4-ethylenedioxythiophene (PEDOT), poly-styrene sulfonic acid (PSS), ceramic materials, etc. In some embodiments of the present disclosure, the polymer layer may be formed by spin coating, spray coating, printing, or the like. In some embodiments, the thickness of the polymer layer is approximately 20 nanometers to 10 microns, or 50 nanometers to 200 nanometers, or 30 to 100 nanometers. For example, the thickness of the polymer layer may be approximately 90 nanometers or 100 nanometers. For the sake of simplicity, the present disclosure does not show a polymer layer.

Since the present disclosure is directed to a phase retardation value of the phase retardation material (i.e., the material of the polymer phase retardation layer 20), the measurement method will be described first. The embodiment of the present disclosure measures the phase retardation value on a plane perpendicular to the direction of the thickness of the object, that is, in-plane retardance/retardation (R₀). The embodiment of the present disclosure uses a commercial device model: AxoScan (manufactured by Axometrics, Inc.) for measuring the in-plane phase retardation value of the object within the wavelength range of visible light (for example, 400-700 nm). For brevity of data, only the in-plane phase retardation value at a specific wavelength, such as 550 nm or 575 nm, is recorded.

Specifically, the difference ΔR of the phase retardation value of the polymer phase retardation layer 20 according to the present disclosure after the reliability test is expressed by the following formula:

ΔR₀=R₀−R₀′

wherein R₀ represents a first phase retardation value of the polymer phase retardation layer 20 in the initial state at a first temperature, R₀′ represents a second phase retardation value measured when the polymer phase retardation layer 20 returns to the first temperature after being kept at a second temperature for a period of time, and ΔR₀ represents the absolute value of the difference between the first phase retardation R₀ and the second phase retardation value R₀′. That is, whether the phase retardation of the polymer phase retardation layer 20 according to the present disclosure will be affected by temperature is judged by the difference ΔR₀ of the phase retardation value, i.e., the difference ΔR₀ after testing at a high temperature (such as 80-100° C.) for a period of time (such as 100, 240, 360, 500 hours or more) is used to estimate the weatherability of the polymer phase retardation layer 20 and products (such as touch elements, anti-reflection elements, displays, etc.) including the polymer phase retardation layer 20 of the embodiment of the present disclosure. The ΔR₀ of the polymer phase retardation layer 20 according to the present disclosure is in the range of 0.1 nm to 2.0 nm. Therefore, it can be judged that the polymer phase retardation layer 20/touch element/anti-reflection element/terminal product according to the present disclosure is not affected by high temperature.

It should be further explained that the difference ΔR₀ of the phase retardation value is ideally zero (that is, the phase retardation value is not affected by temperature). However, the following embodiments of the present disclosure may be subject to the error of the measuring instrument. The difference ΔR₀ of the touch element 40 with the polymer phase retardation layer 20 measured by the measuring instrument used according to the present disclosure is in the range of 0.1 nm to 2.0 nm. However, the user can choose a measuring instrument with a smaller error range to measure the difference ΔR₀ according to the requirements, and thus the measured value may be smaller. This is only an exemplary description, and the present disclosure is not limited to this. In addition, the phase retardation value in the present disclosure can be defined as the one measured in the range of wavelength of the visible light (for example, 400-700 nm), and the difference calculated by the preceding equation is the difference in the phase retardation value at the same wavelength. Alternatively, for convenient explanation, the phase retardation value in the present disclosure can be defined as the one measured at a specific wavelength, such as 550 nm or 575 nm, and the difference calculated by the preceding equation is the difference value of the phase retardation value at 550 nm or 575 nm. In addition, for clarity, if the difference obtained from the foregoing formula is negative, the mathematical calculation of the absolute value is performed.

Specifically, in the present disclosure, the first temperature for performing the above reliability test is room temperature (for example, 25° C.), and the second temperature is 85° C., and the test object is put into a constant temperature and humidity testing machine (model: GTH-408-40-CP-AR, manufactured by GIANT FORCE INSTRUMENT ENTERPRISE CO., LTD.) for 240 hours, then taken out and left at room temperature (for about 5-10 minutes), and then the aforementioned phase retardation value is measured. It should be explained that, the object to be tested is clamped and fixed by upper and lower glass pieces and then is put into the constant temperature and humidity testing machine, and there is a gap between the object to be tested and the upper and lower glass pieces, so that the tested object is exposed to the test environment/conditions in the constant temperature and humidity testing machine.

With reference to Table 1, Table 1 illustrates the phase retardation value R₀ of the polymer phase retardation layer 20 according to the first embodiment of the present disclosure and the conventional liquid crystal phase retardation layer (the liquid crystal phase retardation layer is attached to the substrate by optical glue for phase retardation value measurement) measured at various wavelengths. The phase retardation value R₀ of the two in the range of the visible light are similar. The phase retardation value R₀ of the polymer phase retardation layer 20 according to the first embodiment of the present disclosure measured at a wavelength of 550 nm of the incident light L, is 138.71 nm, which is very close to the ideal phase retardation value R₀ of 138.75 nm. In this way, it can be determined that the polymer phase retardation layer 20 according to the first embodiment of the present disclosure has good optical characteristics, which meets actual application requirements and can replace the aforementioned liquid crystal phase retardation layer.

TABLE 1

| | | Liquid |
|---|---|---|
| Wavelength | Polymer phase | crystal phase |
| (nm) | retardation layer | retardation layer |
| 400 | 171.2 | 160.7 |
| 425 | 161.7 | 157.0 |
| 450 | 155.0 | 154.3 |
| 475 | 150.7 | 150.0 |
| 500 | 145.0 | 144.9 |
| 525 | 141.7 | 144.5 |
| 550 | 138.7 | 137.9 |
| 575 | 136.7 | 137.1 |
| 600 | 134.2 | 138.3 |
| 625 | 132.5 | 135.2 |
| 650 | 132.6 | 131.2 |
| 675 | 128.5 | 130.5 |
| 700 | 130.6 | 132.2 |
| 725 | 129.0 | 130.8 |
| 750 | 128.9 | 127.0 |
| 775 | 127.6 | 127.7 |
| 800 | 122.7 | 125.8 |

It should be further explained that, in general, the touch sensing structure 30 may include indium tin oxide (ITO), metal mesh, silver nanowire (SNW), carbon nanotube (CNT), graphene and other materials, but the present disclosure proposes a combination of silver nanowires/polymer layer composite touch sensing structure 30 and polymer phase retardation layer 20, and when the composite touch sensing structure 30 is used, the measured phase retardation value R₀ measured in the range of the visible light and the measured phase retardation value of the separate polymer phase retardation layer 20 (that is, the composite touch sensing structure 30 is not used) are quite close. For example, the difference between the phase retardation values R₀ of the two is less than 1%. It can be seen from Table 2 that under the test at wavelength of 575 nm, the difference between the first phase retardation value R₀ with the touch sensing structure 30 of the composite type and that without the touch sensing structure 30 of the composite type is calculated to be 0.3%. It can be seen that, according to the aforementioned experiments, the composite touch sensing structure 30 including the silver nanowires/polymer layer and the touch element 40 including the polymer phase retardation layer 20 in the present disclosure has high stability and is suitable for practical requirement for applications. As mentioned above, KR '739 only broadly proposes the possibility of combining the phase retardation layer and the touch sensing module, but KR '739 does not prove that the touch sensing element will not cause the phase retardation layer to have a drift in optical characteristics (such as the phase retardation value). That is, compared with KR '739, the present disclosure proposes a feasible solution for integrating the touch sensing structure made of the silver nanowires/polymer layer and the polymer phase retardation layer, and the polymer phase retardation layer 20 and the composite touch sensing structure 30 including the silver nanowires/polymer layer under this structure can be matched with each other without affecting the characteristics of each other.

However, in general, indium tin oxide (ITO), metal mesh, carbon nanotube (CNT), graphene, and other materials are combined with the polymer phase retardation layer 20. Combining indium tin oxide (ITO), metal mesh, carbon nanotube (CNT), graphene and other materials with the polymer phase retardation layer 20 may cause large variation in the characteristics of the polymer phase retardation layer 20 (such as phase retardation value, etc.). It has been verified by the embodiments of the present disclosure that the composite conductive layer including the silver nanowires/polymer layer (instead of indium tin oxide (ITO), metal mesh, carbon nanotube (CNT), graphene, and other materials that are combined with the polymer phase retardation layer 20) does not have an optical influence on the polymer phase retardation layer 20 (i.e., a difference between a phase retardation value R₀ of the touch element and a phase retardation value R₀ of the polymer phase retardation layer before the touch sensing structure is disposed is less than 1%).

TABLE 2

| Wavelength | | |
|---|---|---|
| (nm) | R₀ without silver nanowire | R₀ with silver nanowire |
| 575 | 148.1 | 147.7 |

Specifically, in the first embodiment of the present disclosure, a composite conductive layer including the silver nanowires/polymer layer is arranged on a polymer phase retardation layer 20 with a thickness of 13 μm according to the aforementioned method, and the phase retardation value is measured after the reliability is tested (that is, the temperature is increased and kept at 85° C. for 240 hours). Please refer to FIG. 5 and Table 3. FIG. 5 is a curve diagram of the difference between the phase retardation value of the touch element according to a first embodiment of the present disclosure and the related art with respect to the wavelength. Table 3 shows the values of the difference ΔR₀ between the phase retardation values of the first embodiment of the present disclosure and the related art measured at a wavelength of 575 nm. According to Table 3, the difference ΔR₀ of the phase retardation value measured at the wavelength of 575 nm in the first embodiment of the present disclosure is 0.7, while the difference ΔR₀ of the phase retardation value measured at the wavelength of 575 nm in the related art is 7.2. FIG. 5 shows that the difference ΔR₀ of the phase retardation value of the first embodiment of the present disclosure is between 0.2 nm to 1.0 nm under the range of the visible light, while the difference ΔR₀ of the phase retardation value of the related art measured under the range of the visible light is larger than 7.0 nm. The optical characteristics of the liquid crystal phase retardation layer used in the related art will be greatly degraded after being subjected to a high temperature environment, the anti-reflection effect is reduced, and thus the quality of the display product degrades. Accordingly, the difference ΔR₀ of the phase retardation value measured after the reliability is tested (that is, the temperature is increased and kept at 85° C. for 240 hours) must be less than 7.0 nm in order to maintain good product quality when used under high temperature environment in the present disclosure.

The difference ΔR₀ of the phase retardation value of the polymer phase retardation layer 20 according to the present disclosure is significantly lower than the difference ΔR₀ of the phase retardation value of the touch element of the related art. Therefore, the polymer phase retardation layer 20 has better weather resistance characteristic. It is worth explaining that although the difference ΔR₀ of the phase retardation value measured at 575 nm in this embodiment is 0.7, the lower limit of ΔR₀ can be reasonably expected to be between even 0 and 0.1 nm with regard to factors such as instrument error, film production tolerances, and batch differences in film materials, so ΔR₀ is between 0 nm and 1.0 nm, 0.1 nm and 1.0 nm, 0.2 nm and 1.0 nm, or 0.7 nm.

TABLE 3

| Liquid crystal retardation layer | | | | Polymer phase retardation layer | | | |
|---|---|---|---|---|---|---|---|
| Wavelength | R₀ | R₀′ | ΔR₀ | Wavelength | R₀ | R₀′ | ΔR₀ |
| 575 | 116.6 | 109.5 | 7.2 | 575 | 142.0 | 141.3 | 0.7 |

In addition, the thickness of the polymer phase retardation layer 20 used in the first embodiment of the present disclosure is only about 13 μm, and the thickness of the overall touch element 40 is 25 μm. By contrast, the total thickness of the touch element in the related art is about 64 μm. The thickness of the embodiment of the present disclosure is greatly reduced. As such, the reduced thickness is advantageous to realize a bendable ultra-thin touch element. Therefore, compared with the conventional technology, the touch element and the product according to the embodiment of the present disclosure have a thinner thickness and higher weather resistance.

It is worth mentioning that, in other embodiments of the present disclosure, the material of the polymer phase retardation layer 20 of the touch element 40 according to the present disclosure can be materials other than colorless polyimide (CPI), such as: cyclo-olefin polymer (COP), triacetyl cellulose (TAC) or polycarbonate (PC), and other film materials.

Table 4 shows the values of the difference ΔR₀ between the retardation value of the second embodiment of the present disclosure and the comparative example using film materials with different thickness. It is understandable that, as for the touch element 40 of the present disclosure, a suitable material can be selected as the material of the polymer phase retardation layer 20 according to requirements in consideration of cost and thickness. According to Table 4, a polymer phase retardation layer 20 with a thickness of 25 μm is used in the second embodiment. The difference ΔR₀ of the phase retardation value measured after the weather resistance is tested at 575 nm is 0.3 nm, which shows that the optical characteristics has less variation compared with the conventional technology, thus the reliability is better. In addition, the thickness of the polymer phase retardation layer 20 used in the second embodiment of the present disclosure is only 25 μm, and the thickness of the overall touch element 40 is 37 μm. The thickness of the embodiment of the present disclosure is greatly reduced compared with the total thickness of the touch element of the related art (64 μm). The reduced thickness is advantageous to realize a bendable ultra-thin touch element.

It is worth explaining that a polymer phase retardation layer 20 with a thickness of 53 μm is used in the comparative example in Table 4. The overall thickness of the touch element 40 is 65 μm, which exceeds the total thickness (64 μm) of the touch element in the related art. Therefore, the polymer phase retardation layer with the thickness of larger than 64 μm is not used in the present disclosure. In this comparative example, the difference ΔR₀ of the phase retardation measured after the weather resistance is tested at 575 nm is 2.0 nm. Therefore, the polymer phase retardation layer 20 used in the present disclosure is distinguished by the thickness of 53 μm, and then the difference of the phase retardation measured at this thickness is converted to the claimed range of the difference of the phase retardation in the embodiment of the present disclosure. That is, ΔR₀ with a value of 2.0 nm can be defined as an upper limit of variation of the difference of the polymer phase retardation layer 20 of the present disclosure after the weather resistance is tested.

TABLE 4

| | Polymer phase retardation | Polymer phase retardation |
|---|---|---|
| | layer (second embodiment) | layer (comparative example) |
| Thickness | 25 μm | 53 μm |
| Wavelength | ΔR₀ | ΔR₀ |
| 575 | 0.3 | 2.0 |

In comprehensive consideration of the second embodiment of the present disclosure and the comparative example, the difference ΔR₀ of the phase retardation of the touch element 40 of the present disclosure can be between 0 nm and 2.0 nm, 0.1 nm and 2.0 nm, 0.2 nm and 2.0 nm, 0.3 nm and 2.0 nm, or can be 0.3 nm.

Other examples of the touch element are provided below, so that a person with ordinary knowledge in the technical field of the present disclosure can understand possible variations more clearly. The elements denoted by the same reference numerals as in the foregoing embodiment are substantially the same as those described above with reference to FIG. 4. The elements, features, and advantages that are the same as those of the touch element 40 will not be repeated.

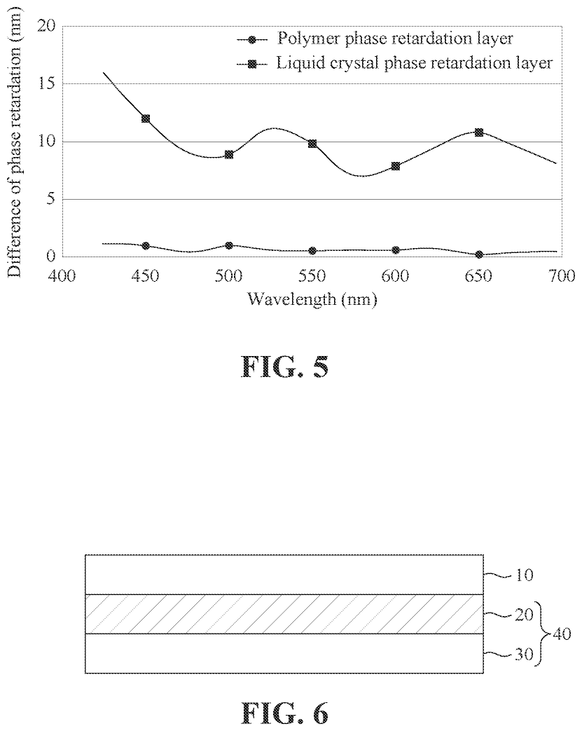

Please refer to FIG. 6, which illustrates other embodiments according to the present disclosure. Compared with FIG. 4, the main structural difference therebetween is that the touch sensing structure 30 of the touch element 40 of this embodiment is disposed under the polymer phase retardation layer 20. The related description of this embodiment will not be repeated here (please refer to the aforementioned description).

Please refer to FIG. 7, which illustrates other embodiments according to the present disclosure. Compared with FIG. 4, the main structural difference therebetween is that the touch sensing structure 30 of the touch element 40 of this embodiment includes the first touch electrode layer 32 and the second touch electrode layer 33. The first touch electrode layer 32 is disposed between the linear polarization layer 10 and the polymer phase retardation layer 20, and the second touch electrode layer 33 is disposed under the polymer phase retardation layer 20. The related description of this embodiment will not be repeated here (please refer to the aforementioned description).

In comprehensive consideration of the first and second embodiments of the present disclosure and the comparative example, the difference ΔR₀ of the phase retardation of the touch element 40 of the present disclosure can be less than 7.0 nm, or between 0 nm and 2.0 nm, 0.1 nm and 2.0 nm, 0.2 nm and 2.0 nm, 0.3 nm and 2.0 nm, 0.2 nm and 1.0 nm, 0.3 nm and 0.7 nm, or 0.7 nm and 2.0 nm. It can be understood that the touch sensing structure 30 arranged at different positions will not affect the difference ΔR₀ of the phase retardation, and those with ordinary knowledge in the technical field of the present disclosure can make various variations and adjustments based on the above examples, which will not be listed here.

Hereinafter, an embodiment in which the touch element according to the present disclosure is applied to a display device will be described.

Please refer to FIG. 8. FIG. 8 is a schematic structural diagram of a display device according to a preferred embodiment of the present disclosure. The display device 300 includes a display panel 200 and a touch element 40. The display panel 200 has a display area. The touch element 40 is disposed on the display panel 200. The touch sensing structure 30 of the touch element 40 correspondingly overlaps the display area. Specifically, the display panel 200 may be, but is not limited to, a liquid crystal display panel (LCD), an organic electroluminescence display panel, an organic light emitting diode display panel, or a micro light emitting diode display panel (μLED display). In another embodiment, the touch element 40 and the linear polarization layer 10 can be constituted to an anti-reflection element, and then be assembled with the display panel 200 to form a terminal product.

Finally, the technical features of the present disclosure and its achievable technical effects at least includes the following:

1. The touch element 40 according to the present disclosure can still have a very low difference of the phase retardation after being kept at a high temperature of 85° C. for 240 hours, so as to enable to achieve a touch element and product with high temperature resistance and good reliability.

2. The polymer phase retardation layer 20 of the touch element 40 according to the present disclosure can be directly used as a substrate without requiring additional substrates, and the thickness of the polymer phase retardation layer 20 of the present disclosure can be selected to be less than 53 μm to produce a bendable ultra-thin touch element. Furthermore, the touch sensing structure 30 of the present disclosure with composite structure, which is made of the polymer phase retardation layer 20 and the silver nanowires, has a good matching characteristic.

The embodiments of the present disclosure are described above with specific embodiments. Those with ordinary knowledge in the technical field can easily understand the technical features, advantages, and effects of the present disclosure from the content disclosed in this specification.

The aforementioned descriptions are only preferred embodiments of the present disclosure, and are not intended to limit the scope of the present disclosure. All other equivalent variations or modifications made without departing from the spirit of the present disclosure should be included in the scope of the following claims.

What is claimed is:

1. A touch element comprising:
a polymer phase retardation layer; and
a touch sensing structure configured to contact with the polymer phase retardation layer, wherein the touch sensing structure is a composite layer of silver nanowires and a polymer,
wherein in a visible light range, a difference between a phase retardation value R₀ of the touch element and a phase retardation value R₀ of the polymer phase retardation layer before the touch sensing structure is disposed is less than 1%.

2. The touch element as claimed in claim 1, wherein a thickness of the touch element is less than 64 μm.

3. The touch element as claimed in claim 1, wherein a thickness of the polymer phase retardation layer is less than 53 μm.

4. The touch element as claimed in claim 3, wherein a phase retardation difference ΔR₀ of the touch element is expressed by the following formula:
ΔR₀=R₀−R₀′
wherein R₀ represents a first phase retardation value of the touch element measured at a wavelength of 575 nm while the touch element has a temperature of about 25° C., R₀′ represents a second phase retardation value of the touch element measured at the wavelength of 575 nm after the touch element lasted for 240 hours at 85° C. and returned to about 25° C., ΔR₀ represents an absolute value of a difference between the first phase retardation value and the second phase retardation value, and the ΔR₀ is less than 7.0 nm.

5. The touch element as claimed in claim 4, wherein the ΔR₀ is between 0 nm and 2.0 nm.

6. The touch element as claimed in claim 1, wherein a thickness of the polymer phase retardation layer is about 13 μm, and a phase retardation difference ΔR₀ of the touch element is expressed by the following formula:
ΔR₀=R₀−R₀′
wherein R₀ represents a first phase retardation value of the touch element measured at a wavelength of 575 nm while the touch element has a temperature of about 25° C., R₀′ represents a second phase retardation value of the touch element measured at the wavelength of 575 nm after the touch element lasting for 240 hours under 85° C. and then measured at 575 nm of the wavelength after returning back to about 25° C., ΔR₀ represents an absolute value of a difference between the first phase retardation value and the second phase retardation value, and the ΔR₀ is between 0 nm and 1.0 nm, 0.1 nm and 1.0 nm, 0.2 nm and 1.0 nm, or is 0.7 nm.

7. The touch element as claimed in claim 1, wherein a thickness of the polymer phase retardation layer is about 25 μm, and a phase retardation difference ΔR₀ of the touch element is expressed by the following formula:
ΔR₀=R₀−R₀′
wherein R₀ represents a first phase retardation value of the touch element measured at a wavelength of 575 nm while the touch element has a temperature of about 25° C., R₀′ represents a second phase retardation value of the touch element measured at the wavelength of 575 nm after the touch element lasted for 240 hours at 85° C. and returned to about 25° C., ΔR₀ represents an absolute value of a difference between the first phase retardation value and the second phase retardation value, and the ΔR₀ is between 0 nm and 2.0 nm.

8. The touch element as claimed in claim 1, wherein the touch element is assembled in a linear polarization layer.

9. A display device comprising:
a display panel having a display area; and
the touch element as claimed in claim 1 disposed on the display panel, wherein the touch sensing structure of the touch element correspondingly overlaps the display area.

10. The touch element as claimed in claim 4, wherein the ΔR₀ is between 0.1 nm and 2.0 nm.

11. The touch element as claimed in claim 4, wherein the ΔR₀ is between 0.2 nm and 2.0 nm.

12. The touch element as claimed in claim 4, wherein the ΔR₀ is between 0.3 nm and 2.0 nm.

13. The touch element as claimed in claim 4, wherein the ΔR₀ is between 0.2 nm and 1.0 nm.

14. The touch element as claimed in claim 4, wherein the ΔR₀ is between 0.3 nm and 0.7 nm.

15. The touch element as claimed in claim 4, wherein the ΔR₀ is between 0.7 nm and 2.0 nm.

16. The touch element as claimed in claim 1, wherein a thickness of the polymer phase retardation layer is about 13 μm, and a phase retardation difference ΔR₀ of the touch element is expressed by the following formula:
ΔR₀=R₀−R₀′
wherein R₀ represents a first phase retardation value of the touch element measured at a wavelength of 575 nm while the touch element has a temperature of about 25° C., R₀′ represents a second phase retardation value of the touch element measured at the wavelength of 575 nm after the touch element lasted for 240 hours at 85° C. and returned to about 25° C., ΔR₀ represents an absolute value of a difference between the first phase retardation value and the second phase retardation value, and the ΔR₀ is between 0.1 nm and 1.0 nm.

17. The touch element as claimed in claim 1, wherein a thickness of the polymer phase retardation layer is about 13 μm, and a phase retardation difference ΔR₀ of the touch element is expressed by the following formula:
ΔR₀=R₀−R₀′
wherein R₀ represents a first phase retardation value of the touch element measured at a wavelength of 575 nm while the touch element has a temperature of about 25° C., R₀′ represents a second phase retardation value of the touch element measured at the wavelength of 575 nm after the touch element lasted for 240 hours at 85° C. and returned to about 25° C., ΔR₀ represents an absolute value of a difference between the first phase retardation value and the second phase retardation value, and the ΔR₀ is between 0.2 nm and 1.0 nm.

18. The touch element as claimed in claim 1, wherein a thickness of the polymer phase retardation layer is about 13 μm, and a phase retardation difference ΔR₀ of the touch element is expressed by the following formula:
ΔR₀=R₀−R₀′
wherein R₀ represents a first phase retardation value of the touch element measured at a wavelength of 575 nm while the touch element has a temperature of about 25° C., R₀′ represents a second phase retardation value of the touch element measured at the wavelength of 575 nm after the touch element lasted for 240 hours at 85° C. and returned to about 25° C., ΔR₀ represents an absolute value of a difference between the first phase retardation value and the second phase retardation value, and the ΔR₀ is between 0.7 nm.

19. The touch element as claimed in claim 1, wherein a thickness of the polymer phase retardation layer is about 25 μm, and a phase retardation difference ΔR₀ of the touch element is expressed by the following formula:
ΔR₀=R₀−R₀′
wherein R₀ represents a first phase retardation value of the touch element measured at a wavelength of 575 nm while the touch element has a temperature of about 25° C., R₀′ represents a second phase retardation value of the touch element measured at the wavelength of 575 nm after the touch element lasted for 240 hours at 85° C. and returned to about 25° C., ΔR₀ represents an absolute value of a difference between the first phase retardation value and the second phase retardation value, and the ΔR₀ is between 0.1 nm and 2.0 nm.

20. The touch element as claimed in claim 1, wherein a thickness of the polymer phase retardation layer is about 25 μm, and a phase retardation difference ΔR₀ of the touch element is expressed by the following formula:
ΔR₀=R₀−R₀′
wherein R₀ represents a first phase retardation value of the touch element measured at a wavelength of 575 nm while the touch element has a temperature of about 25° C., R₀′ represents a second phase retardation value of the touch element measured at the wavelength of 575 nm after the touch element lasted for 240 hours at 85° C. and returned to about 25° C., ΔR₀ represents an absolute value of a difference between the first phase retardation value and the second phase retardation value, and the ΔR₀ is between 0.2 nm and 2.0 nm.
